(19) United States
(12) Patent Application Publication
(10) Pub. No.: US 2007/0258120 A1
(43) Pub. Date: Nov. 8, 2007

(54) Micro-electro mechanical system scanner having structure for correcting declined scan line

(75) Inventors: Young-chul Ko, Yongin-si (KR); Jin-woo Cho, Yongin-si (KR); Yong-hwa Park, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/707,956

(22) Filed: Feb. 20, 2007

(30) Foreign Application Priority Data
May 3, 2006 (KR) 10-2006-0040083

(51) Int. Cl. B81B 7/02

(52) U.S. Cl. 359/199

(57) ABSTRACT

A micro-electro mechanical system (MEMS) scanner. The MEMS scanner includes a first frame rotationally vibrated about an axle according to a low-frequency vertical scan function, a second frame supported coaxially with and rotationally on the first frame, a vibration member disposed between the first frame and the second frame so as to vibrate the second frame with respect to the first frame according to a high-frequency vertical scan function. A MEMS mirror which receives a vertical scan motion of the second frame and simultaneously operates in a rotational vibration mode about an axle according to a high-frequency horizontal scan function so as to two-dimensionally scan a screen with incident light. Therefore, scan lines are uniformly produced in a scanning direction and, thus, pixels can be uniformed arranged across a screen, increasing the vertical resolution of the screen and providing high-quality images.

### CROSS-REFERENCE TO RELATED PATENT APPLICATION

This application claims the benefit of Korean Patent Application No. 10-2006-0040083, filed on May 3, 2006, in the Korean Intellectual Property Office, the disclosure of which is incorporated herein in its entirety by reference.

### BACKGROUND OF THE INVENTION

1. Field of the Invention

Apparatuses and methods consistent with the present invention relate to a micro-electro mechanical system (MEMS) scanner, and more particularly, to a MEMS scanner having a correcting structure for uniformly arranging scan lines in a scanning direction and increasing the vertical resolution of a screen.

2. Description of the Related Art

A MEMS scanner is a kind of light scanning device that is used in a display device or a scanning apparatus. In the display device, the MEMS scanner scans a screen with a light beam emitted from a light source so as to display an image on the screen. In the scanning apparatus, the MEMS scanner scans an image with light and receives reflected light from the image so as to read image data. The MEMS scanner has a small size and integrated structure since it is manufactured using micro-machining technologies.

In a MEMS scanner, a reflective surface is provided to allow the reflection of incident light. While the reflective surface is vibrated with respect to different axles, a light beam emitted from a light source is deflected from the reflection surface onto a screen in horizontal and vertical scanning directions. As the light beam is repeatedly deflected from the reflective surface within a predetermined horizontal angle range, the light beam forms a plurality of scan lines on the screen. The horizontal angle of the light beam can vary in the form of sinusoidal waves having a high frequency, as shown in FIG. 1A. In FIG. 1A, the horizontal axis represents time, and the vertical axis represents the horizontal scan angle. After scanning is completed for an image (one frame) whereby a light beam spot is moved from an upper end of a screen to a lower end of the screen, the light beam spot is moved back to the upper end of the screen. For this, the light beam (scanning beam) is repeatedly moved up and down within a predetermined angle range in a vertical direction of the screen. Referring to FIG. 1B, the vertical angle of the scanning beam can vary in the form of a descent ramp. Here, the descent ramp corresponds to the amount the vertical angle of the scanning beam varies during scanning of one image. Therefore, to display a plurality of images on the screen, the vertical angle of the scanning beam may periodically vary in the form of sawtooth waves having a descent ramp and an abruptly rising ramp for returning to an original position.

FIG. 1C is a view illustrating a two-dimensional scan path produced on a screen by the combination of the sinusoidal horizontal scan function and the vertical scan function having a ramp shape. Referring to FIG. 1C, a number of scan lines are produced in an effective screen region for displaying an image on the screen. Light is modulated according to a piece of image data corresponding to one frame, and the screen is scanned with the modulated light in order to display an image (one frame) on the screen. Each of the scan lines formed in the effective screen region declines downward in an advancing direction, and thus a zigzagging pattern is formed by the scanning lines. Therefore, the distance between two neighboring scan lines cannot be uniformly maintained. That is, the distance between two neighboring scan lines gradually increases or decreases, and sharp edges are formed at both sides of the screen. The reason for this is that horizontal scanning and vertical scanning are simultaneously performed. As a result, image distortion occurs at edge portions of the screen, and thus images that are different from the desired images are displayed on the screen. Furthermore, since the vertical distance between pixels cannot be uniformly maintained, the vertical resolution of the screen is deteriorated.

### SUMMARY OF THE INVENTION

Exemplary embodiments of the present invention provide a micro-electro mechanical system (MEMS) scanner and method that uniformly arrange pixels by making horizontal scan lines uniform in a scanning direction.

Exemplary embodiments of the present invention also provide a MEMS scanner that cane provide a high-resolution image by improving the vertical resolution of a screen.

Exemplary embodiments of the present invention further provide a MEMS scanner having a scan pattern correcting structure integrally formed with an existing structure of the MEMS scanner which results in a decrease the size of the MEMS scanner.

According to an aspect of the exemplary embodiments of the present invention, there is provided an MEMS scanner comprising: a first frame rotationally vibrating about an axle according a low-frequency vertical scan function; a second frame supported coaxially with and rotatably on the first frame; a vibration member disposed between the first frame and the second frame so as to vibrate the second frame with respect to the first frame according to a high-frequency vertical scan function; and a MEMS mirror receiving a vertical scan motion of the second frame and rotationally vibrating about another axle according to a high-frequency horizontal scan function so as to two-dimensionally scan a screen with incident light.

The low-frequency vertical scan function may comprise sawtooth waves having different rising and falling intervals that repeat at a low frequency. The high-frequency vertical scan function may comprise sawtooth waves having different rising and falling intervals that repeat at a high frequency. The high-frequency horizontal scan function may comprise sinusoidal waves having a high frequency. The MEMS mirror may vibrate in a resonant mode according to the high-frequency horizontal scan function. The high-frequency vertical scan function may have a frequency twice as large as that of the high-frequency horizontal scan function.

The second frame may vibrate according to a step function having a low-frequency vertical scan component of the first frame and a high-frequency vertical scan ripple component of the vibration member. In this case, while the MEMS mirror scans the screen for one frame, a scan beam irradiated from the MEMS mirror onto the screen may move down in a vertical direction in a step-by-step manner. The MEMS scanner may stop vertical scanning while performing horizontal scanning when horizontal scan line progresses horizontally. When the horizontal scanning is completed for one horizontal scan line, the MEMS scanner may resume the vertical scanning in order to move down a scan beam spot in an abruptly falling manner.

The MEMS scanner may further comprise an outer frame coaxially connected to the first frame for rotation with the first frame, wherein the first frame is vibrated by an actuator connected to the outer frame according to a low-frequency vertical scan function.

The MEMS mirror may rotationally vibrate according to the high-frequency horizontal scan function by receiving a corresponding torque from an outer frame additionally disposed around the first frame.

The vibration member may vibrate the second frame by using one of an electrostatic method, an electromagnetic method, and a piezoelectric method.

The MEMS scanner may further comprise an outer frame, wherein the second frame, the first frame, and the outer frame are sequentially disposed around the MEMS mirror, the MEMS mirror and the second frame are connected to each other by a horizontal scan axle, and the first frame and the outer frame are coaxially supported by a vertical scan axle.

According to another exemplary aspect of the present invention, there is provided a MEMS scanner comprising: a two-dimensional scanner including a reflective surface rotationally vibrated about different axles, the reflective surface reflecting light, from a light source, incident on a screen in a horizontal direction and a vertical direction, the reflective surface being rotationally vibrated about one axle according to a high-frequency horizontal scan function and being rotationally vibrated about the other axle according to a low-frequency vertical scan function; a compensation scanner disposed in parallel to the two-dimensional scanner and including a reflection surface vibrated according to a high-frequency vertical scan function; and a reflection mirror optically connecting the two-dimensional scanner and the compensation scanner.

The two-dimensional scanner may be disposed prior to the compensation scanner along an optical path. Alternatively, the compensation scanner may be disposed prior to the two-dimensional scanner along an optical path.

The MEMS scanner may perform vertical scanning in a step-by-step falling pattern by combining a low-frequency vertical scan component of the two-dimensional scanner and a high-frequency vertical scan component of the compensation scanner.

The two-dimensional scanner and the compensation scanner may be placed on the same plane, and the reflection mirror may be disposed above the two-dimensional scanner and the compensation scanner. The two-dimensional scanner and the compensation scanner may be packaged into a single chip.

According to another aspect of the invention, there is provided a method of vibrating a micro-electro mechanical system (MEMS) scanner comprising rotationally vibrating a first frame about an axle according to a low-frequency vertical scan function; coaxially supporting a second frame with respect to the first frame, such that the second frame is rotatable with respect to the first frame; vibrating the second frame with respect to the first frame by a vibration member disposed between the first frame and the second frame according to a high-frequency vertical scan function; and receiving, by a MEMS mirror, a vertical scan motion of the second frame and rotationally vibrating the MEMS mirror about another axle according to a high-frequency horizontal scan function so as to two-dimensionally scan a screen with incident light.

The low-frequency vertical scan function may comprise sawtooth waves having different rising and falling intervals that repeat at a low frequency for the low-frequency vertical scan function. The high-frequency vertical scan function may comprise sawtooth waves having different rising and falling intervals that repeat at a high frequency. The high-frequency horizontal scan function may comprise sinusoidal waves having a high frequency. The MEMS mirror may be vibrated in a resonant mode according to the high-frequency horizontal scan function.

The method may further comprise vibrating the second frame according to a step function having a low-frequency vertical scan component of the first frame and a high-frequency vertical scan ripple component of the vibration member. Also, the method may comprise irradiating a scan beam from the MEMS mirror onto the screen such that the scan beam moves down in a vertical direction in a step-by-step manner while the MEMS mirror scans the screen for one frame. It is also contemplated that the method comprises stopping vertical scanning while performing horizontal scanning, and when the horizontal scanning is completed for one horizontal scan line, resuming the vertical scanning in order to move down a scan beam spot in a falling manner.

An outer frame may be coaxially connected to the first frame for rotation with the first frame, and the first frame may be vibrated by an actuator connected to the outer frame according to a low-frequency vertical scan function. The MEMS mirror may be rotationally vibrated according to the high-frequency horizontal scan function by receiving a torque from an outer frame additionally disposed around the first frame. The second frame may be vibrated by the vibration member by using one of an electrostatic method, an electromagnetic method, and a piezoelectric method.

The method further contemplates providing an outer frame, and sequentially disposing the second frame, the first frame, and the outer frame around the MEMS mirror, connecting the MEMS mirror and the second frame to each other by a horizontal scan axle, and coaxially supporting the first frame and the outer frame by a vertical scan axle.

### BRIEF DESCRIPTION OF THE DRAWINGS

The above and other aspects of the present invention will become more apparent by describing in detail exemplary embodiments thereof with reference to the attached drawings in which:

FIGS. 1A and 1B are views illustrating a conventional two-dimensional method of scanning a screen, in which a horizontal scan angle and a vertical scan angle of a scanning beam are respectively plotted as a function of time;

FIG. 1C is a view illustrating a two-dimensional scan path formed on a screen according to the horizontal scan angle and the vertical scan angle depicted in FIGS. 1A and 1B;

FIG. 2 is a plan view illustrating a micro-electro mechanical system (MEMS) scanner according to an exemplary embodiment of the present invention;

FIG. 3 is a vertical cross-sectional view taken along the line III-III of FIG. 2 according to an exemplary embodiment of the present invention;

FIGS. 4A and 4B are cross-sectional views illustrating supporting structures of a vibration unit according to exemplary embodiments of the present invention;

FIG. 5 is a graph illustrating a horizontal scan function that can be used to scan a surface in a horizontal direction according to an exemplary embodiment of the present invention;

FIGS. 6A and 6B are graphs illustrating a low-frequency vertical scan function and a high-frequency vertical scan function, respectively, that can be used for vertical scanning according to exemplary embodiments of the present invention;

FIG. 6C is a graph illustrating a vertical scan function obtained by synthesizing the low-frequency vertical scan function depicted in FIG. 6A and the high-frequency vertical scan function depicted in FIG. 6B;

FIG. 6D is an enlarged view illustrating a portion A of FIG. 6C;

FIG. 7 is a view illustrating a two-dimensional scan path formed on a screen using the horizontal scan function depicted in FIG. 5 and the vertical scan function depicted in FIG. 6D according to an exemplary embodiment of the present invention;

FIG. 8 is a view illustrating a system equivalent to a vertical scan vibration structure of the MEMS scanner depicted in FIG. 2;

FIGS. 9A and 9B are profile graphs of exciting forces F₀ and F_{pzt} of the equivalent system depicted in FIG. 8;

FIG. 9C is a graph illustrating an analysis result for a translational displacement X₂ of the equivalent system depicted in FIG. 8;

FIG. 9D is a graph illustrating an analysis result for a translational displacement X₀ of the equivalent system depicted in FIG. 8;

FIG. 9E is a graph illustrating an analysis result for a translational displacement X₁ of the equivalent system depicted in FIG. 8;

FIG. 10 is a graph illustrating a high-frequency vertical scan function according to an exemplary embodiment of the present invention; and

FIG. 11 is a vertical cross-sectional view of a MEMS scanner according to another exemplary embodiment of the present invention.

### DETAILED DESCRIPTION OF EXEMPLARY EMBODIMENTS OF THE INVENTION

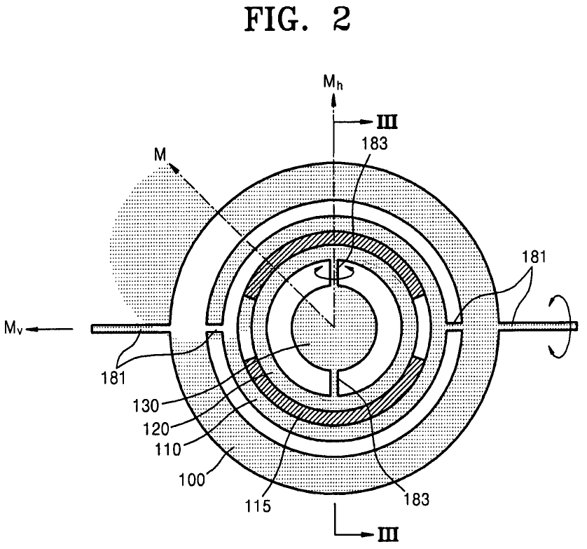

The present invention will now be described more fully with reference to the accompanying drawings, in which exemplary embodiments of the invention are shown. FIG. 2 is a plan view illustrating a micro-electro mechanical system (MEMS) scanner according to an exemplary embodiment of the present invention. The MEMS scanner includes a central MEMS mirror 130, an outer frame 100, a first frame 110, and a second frame 120. The MEMS mirror 130 scans a surface by reflecting light onto the surface while rotationally vibrating on a vertical scan axle 181 or a horizontal scan axle 183. The frames 100, 110, and 120 are coaxially formed around the MEMS mirror 130 so as to directly or indirectly support the MEMS mirror 130 by means of the axles 181 and 183. The MEMS mirror 130 rotates about the horizontal scan axle 183 in order to perform horizontal scanning by reflecting light from a light source (not shown) that is incident on its reflective surface. This horizontal scan motion of the MEMS mirror 130 can be obtained by exciting the outer frame 100 at a high frequency. That is, the outer frame 100 can be excited by a vibration actuator (not shown) so as to be vibrated about a line between the vertical scan axle 181 and the horizontal scan axle 183. For example, the outer frame 100 can be excited for rotational vibration about a 45-degree line between the vertical and horizontal scan axles 181 and 183. Here, an exciting torque (M) applied to the outer frame 100 from the vibration actuator can be divided into a horizontal scan component Mₕ acting about the horizontal scan axle 183 and a vertical scan component Mᵥ acting about the vertical scan axle 181. While the MEMS mirror 130 is vibrated about the horizontal scan axle 183 at a high-frequency by the horizontal scan component Mₕ, the MEMS mirror 130 reflects incident light onto a scan surface in a horizontal direction. For example, the MEMS mirror 130 can be vibrated at a frequency of 25 kHz. In order to allow the MEMS mirror 130 to vibrate in resonance mode, the dimensions and weight of the MEMS mirror 130 and the elastic strength of the horizontal scan axle 183 must be properly determined.

In this way, the horizontal scan component Mₕ of the exciting torque (M) causes the MEMS mirror 130 to vibrate in resonance mode. Meanwhile, the vertical scan component Mᵥ of the exciting torque (M) cannot practically cause the MEMS mirror 130 to vibrate due to an anisotropic vibration characteristic of the MEMS scanner. In detail, since the outer frame 100 and the first frame 110 that are rotatable about the vertical scan axle 181 are designed to have a low resonant frequency, the outer frame 100 and the first frame 110 barely respond to the high-frequency exciting torque (M).

Meanwhile, after the MEMS mirror 130 reflects light for one horizontal scan line, the MEMS mirror 130 is rotated about the vertical scan axle 181 to the next position so as to reflect light for the next horizontal scan line. For this, the frames 100, 110, and 120 formed around the MEMS mirror 130 are rotationally vibrated about the vertical scan axle 181 so as to excite the MEMS mirror 130. This will now be described in more detail.

The outer frame 180 is rotationally vibrated about the vertical scan axle 181 by the vibration actuator (not shown). For example, the outer frame 100 can be vibrated at a low frequency of 60 Hz. The first frame 110 is disposed inside the outer frame 100 and connected to the outer frame 100 by means of the vertical scan axle 181. The first frame 110 receives most of the low-frequency vibration of the outer frame 100 by means of the vertical scan axle 181.

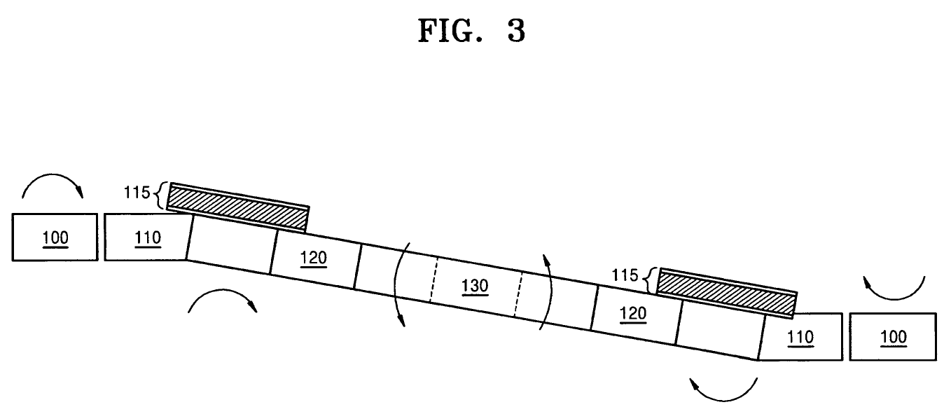

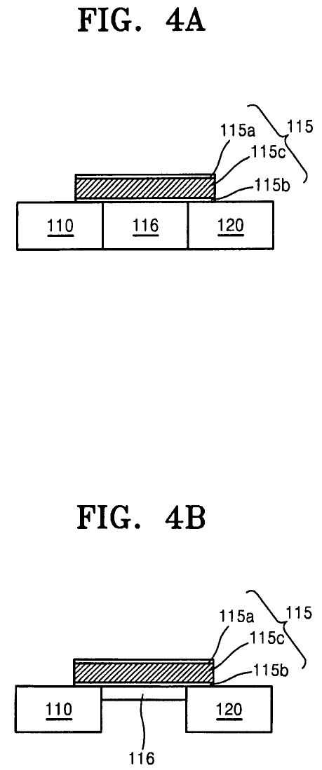

The second frame 120 is disposed inside the first frame 110 and is connected to the first frame 110 through a vibration member 115. For example, the vibration member 115 can be formed of a lead zirconate titanate (PZT) piezoelectric material. The vibration member 115 vibrates the second frame 120 about the vertical scan axle 181 at a high frequency of, for example, 50 kHz. Therefore, the second frame 120 receives vibration motions both from the first frame 110 and the vibration member 115. That is, the low-frequency vibration of the outer frame 100 is transmitted to the second frame 120 through the first frame 110, and the high-frequency vibration of the vibration member 115 is directly transmitted to the second frame 120. As a result, the second frame 120 exhibits a combined scan motion having a low-frequency vertical vibration component and a high-frequency vibration component. FIG. 3 is a vertical cross-sectional view taken along the line III-III of FIG. 2 according to an exemplary embodiment of the present invention. When the outer frame 100 is vibrated at a low frequency and the vibration member 115 formed between the first and second frames 110 and 120 is vibrated at a high frequency, the second frame 120 exhibits a complex vibration having a low-frequency component and a high-frequency ripple component added to the low-frequency component. The MEMS mirror 130 and the frames 100, 110, and 120 supporting the MEMS mirror 130 can be integrally formed using a semiconductor manufacturing process. For example, the MEMS mirror 130 and the frames 100, 110, and 120 can be integrally formed by etching a silicon substrate into a predetermined pattern. The vibration member 115 can be coupled to the etched silicon substrate. Referring to FIGS. 4A and 4B, a supporting member 116 is provided in order to support the vibration member 115. The supporting member 116 can have the same thickness as the first and second frames 110 and 120 as shown in FIG. 4A. Alternatively, the supporting member 116 can have a thickness smaller than that of the first and second frames 110 and 120 so as to increase the flexibility and responsiveness of the supporting member 116 with respect to the vibration of the vibration member 115. The vibration member 115 can include a piezoelectric layer 115c, and two metal electrodes 115a and 115b that are respectively formed on both sides of the piezoelectric layer 115c. However, instead of using a piezoelectric material, the vibration member 115 can be formed of other materials such as an electrostatic material and an electro-magnetic material, as long as the vibration member 115 can generate a mechanical vibration from a driving pulse input.

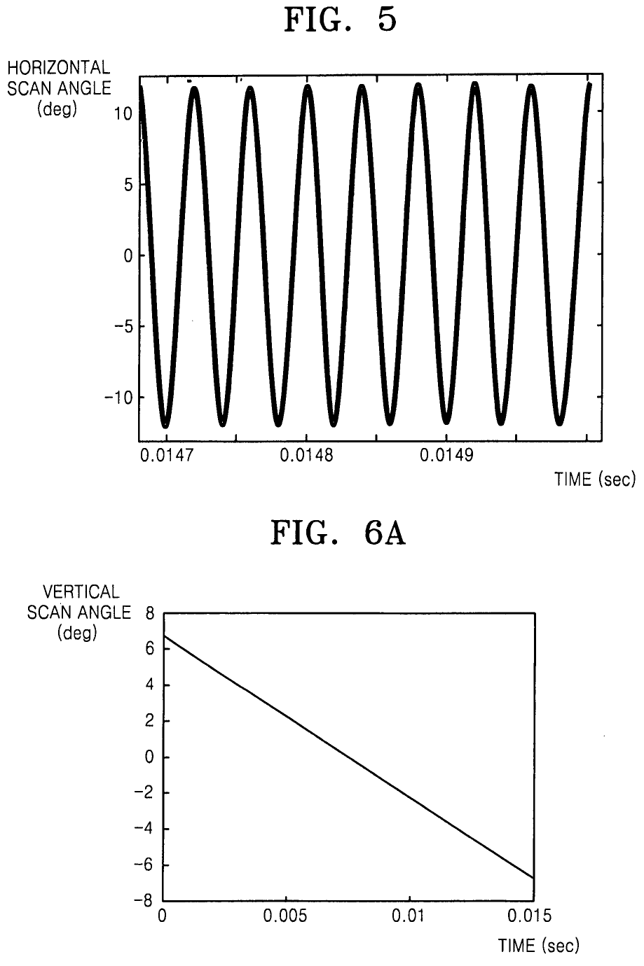

FIG. 5 is a graph illustrating a horizontal scan function that can be used to scan a surface in a horizontal direction according to an exemplary embodiment of the present invention. In FIG. 5, the horizontal axis represents time, and the vertical axis represents a horizontal scan angle. Referring to FIG. 5, the horizontal scan function is a sinusoidal function having an upper limit of +12°, a lower limit of −12°, and a frequency of 25 kHz. During half the period of the sinusoidal function, horizontal scanning is performed for one scan line. That is, a scan beam reflected from the MEMS mirror 130 forms scan lines while vibrating between +12° and −12°. The upper and lower angle limits respectively correspond to either end of a horizontal scan line.

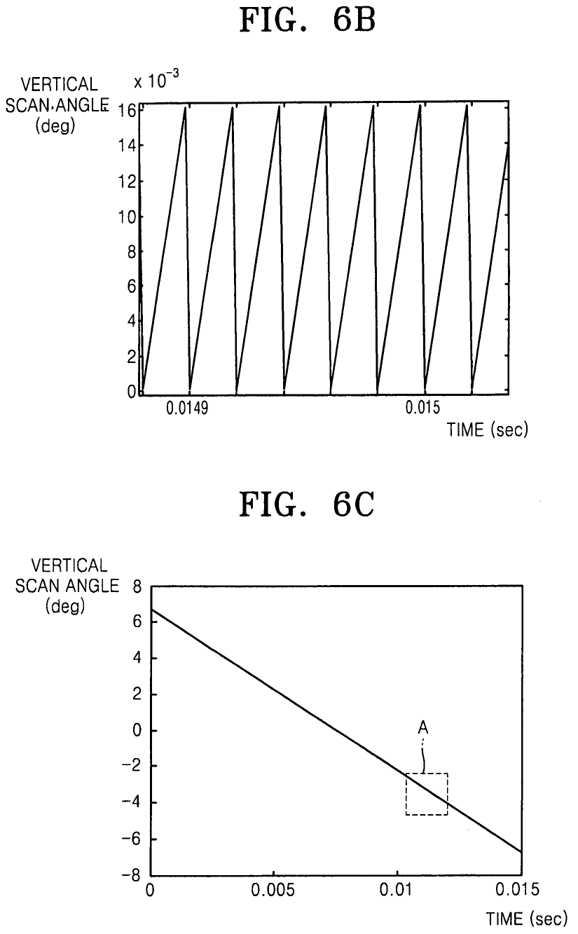

FIGS. 6A and 6B are graphs respectively illustrating a low-frequency vertical scan function and a high-frequency vertical scan function that can be used for vertical scanning according to exemplary embodiments of the present invention. Referring to FIG. 6A, when one image (frame) is formed on a screen, the low-frequency vertical scan function exhibits a simple descent ramp. To display a moving picture including many images, the low-frequency vertical scan function exhibits sawtooth waves in which a slowly falling ramp and a steeply rising ascent ramp are periodically repeated. For example, the saw tooth waves can be repeated between an upper limit of +6.78° and a lower limit of −6.78° at a frequency of 60 Hz. According to the low-frequency vertical scan function, a vertical scan motion is generated in order to move a scanning line in a vertical direction.

Referring to FIG. 6B, the high-frequency vertical scan function is a sawtooth wave function having a high frequency and a relatively small scan angle range of, for example, 0° to +0.0162°. Each sawtooth wave can have a relatively non-steep rising ramp and a relatively steep falling ramp as shown in FIG. 6B. The high-frequency vertical scan function is used to generate a vertical scan motion for correcting a scan line distortion caused by low-frequency scanning. The high-frequency vertical scan function may have a frequency twice as large as that of the horizontal scan function. For example, when the horizontal scan function has a frequency of 25 kHz, the high-frequency vertical scan function can have a frequency of 50 kHz. In the exemplary MEMS scanner depicted in FIG. 2, the outer frame 100 can be vibrated according to the low-frequency vertical scan function shown in FIG. 6A, and a driving pulse input can be applied to the vibration member 115 disposed between the first and second frames 110 and 120 according to the high-frequency vertical scan function shown in FIG. 6B. In this case, the second frame 120 can be vibrated in a combination mode of the low- and high-frequency vertical scan functions of FIGS. 6A and 6B. Here, the high-frequency component of the combination vibration of the second frame 120 is not transmitted to the first frame 110 or the outer frame 100.

FIG. 6C is a graph illustrating a vertical scan function obtained by synthesizing the low-frequency vertical scan function depicted in FIG. 6A and the high-frequency vertical scan function depicted in FIG. 6B, and FIG. 6D is an enlarged view illustrating the portion “A” of FIG. 6C. The vertical scan function illustrated in FIG. 6C exhibits a generally declining ramp having a low frequency, and a high-frequency ripple component is added to the declining ramp as shown in FIG. 6D. Therefore, the vertical scan function has a form of a generally-declining step function.

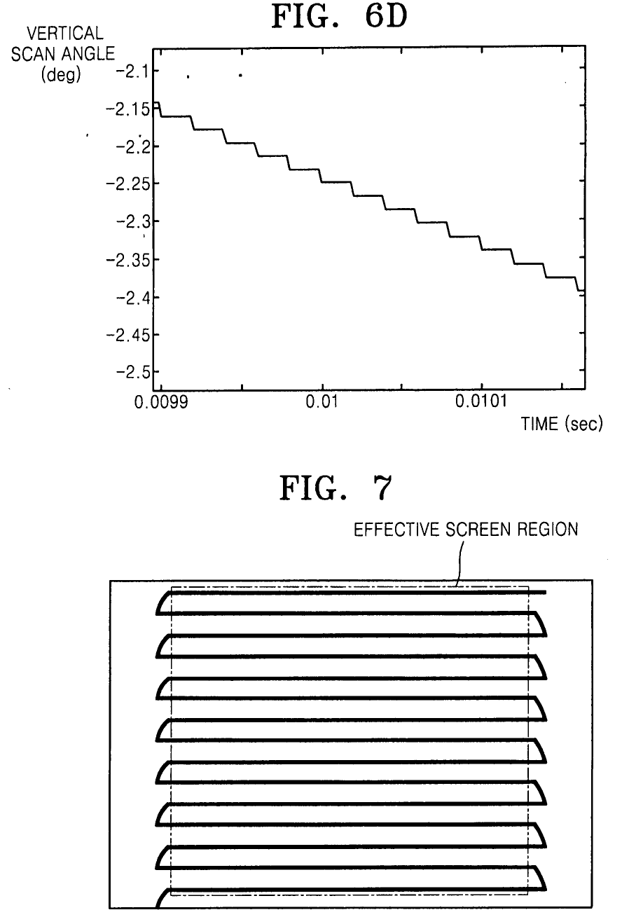

FIG. 7 is a view illustrating a two-dimensional scan path formed on a screen using the horizontal scan function (sinusoidal function) depicted in FIG. 5 and the vertical scan function (having a generally-declining step function form) depicted in FIG. 6D according to an exemplary embodiment of the present invention. Referring to FIG. 7, a number of horizontal scan lines are produced on an effective region of a screen in order to provide an image. The distance between the horizontal scan lines is uniformly maintained. Since the vertical scan function is in the form of a step function, vertical scanning is not performed during horizontal scanning, and thus the horizontal scan lines can be produced substantially in a horizontal direction at uniform intervals. After one horizontal scan line is produced by horizontal scanning, vertical scanning is performed outside the effective screen region to move down the scan line by a predetermined pitch. Then, the horizontal scanning is performed again in order to produce the next horizontal scan line.

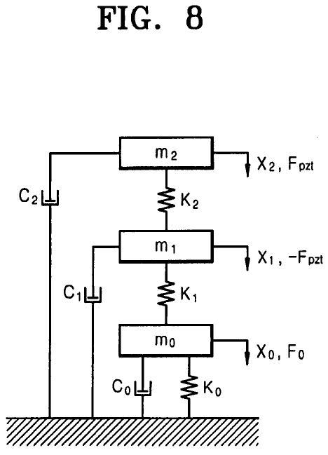

FIG. 8 is a view illustrating a system equivalent to a vertical-scan vibration structure of the MEMS scanner depicted in FIG. 2. The one-dimensional rotational vibration of the MEMS scanner for the vertical scanning is modeled as a one-dimensional translational vibration. In detail, the outer frame 100, the first frame 110, and the second frame 120 (rotary elements) are modeled as concentrated masses m₀, m₁, and m₂, respectively, and rotational displacements of the rotary elements correspond to translational displacements X₀, X₁, and X₂, respectively. Since the second frame 120 exhibits the same vertical scan motion as the MEMS mirror 130 disposed inside the second frame 120 and connected to the second frame 120, the translational displacement X₂ represents the displacement of the MEMS mirror 130 as well as the displacement of the second frame 120. Meanwhile, the vertical scan axle 181 and the vibration member 115 that connect the frames 100, 110, and 120 are modeled as elastic members K₀, K₁, and K₂ and damping members C₀, C₁, and C₂.

Vibration equations of the equivalent system shown in FIG. 8 can be expressed by Equation 1.

m₂\ddot{x}₁+c₂\dot{x}₂+k₂(x₂−x₁)=F_{pzt}

m₁\ddot{x}₂+c₁\dot{x}₁+(k₂+k₁)x₁−k₂x₂−k₁x₀=−F_{pzt}

m₀\ddot{x}₀+c₀\dot{x}₀+(k₁+k₀)x₀−k₁x₁=F₀ [Equation 1]

In order to perform a numerical analysis on the equivalent system shown in FIG. 8, all the system variables, such as masses m₀, m₁, and m₂, elastic coefficients K₀, K₁, and K₂, and damping constants C₀, C₁, and C₂, should be determined. In consideration of resonant frequencies of the frames 100, 110, and 120 determined by the masses m₀, m₁, and m₂, and elastic strengths, the system variables can be determined so that the masses m₁ and m₂ have a resonant frequency of 8 kHz, and the mass m₀ has a resonant frequency of 800 Hz.

The mass m₀ is vibrated by an exciting force F₀ at a low frequency, and the masses m₁ and m₂ are vibrated by exciting forces −F_{pzt} and F_{pzt} at high frequencies. Here, as action-reaction forces, the exciting forces −F_{pzt} and F_{pzt} are exerted on the masses m₁ and m₂ at the same amplitude in opposite directions. The mass m₂ receives a low-frequency vibration from the mass m₀ and a high-frequency vibration from the mass m₁, so that the mass m₂ exhibits a vibration having a low-frequency component and a high-frequency ripple component.

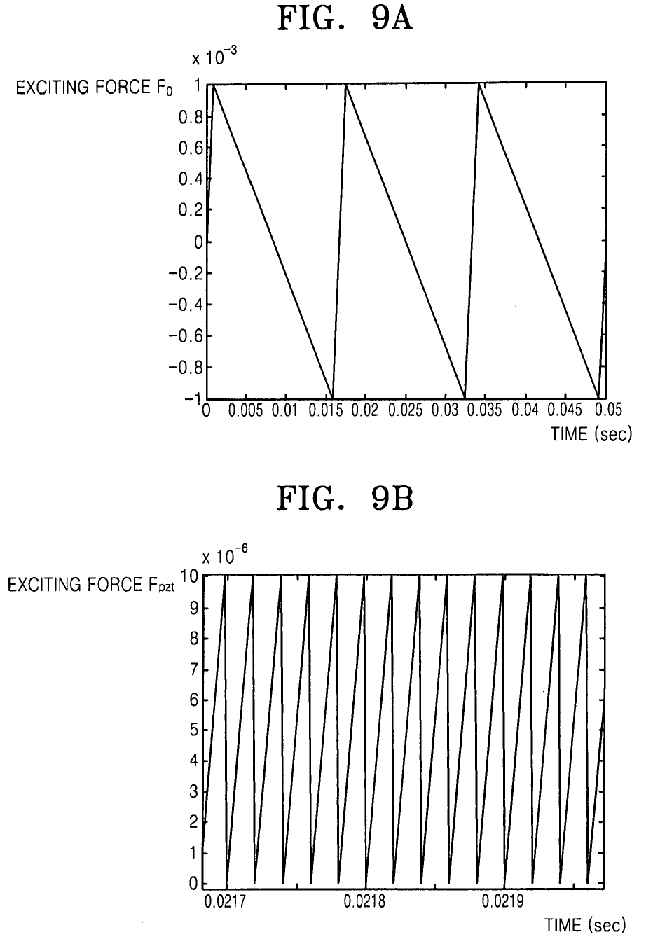

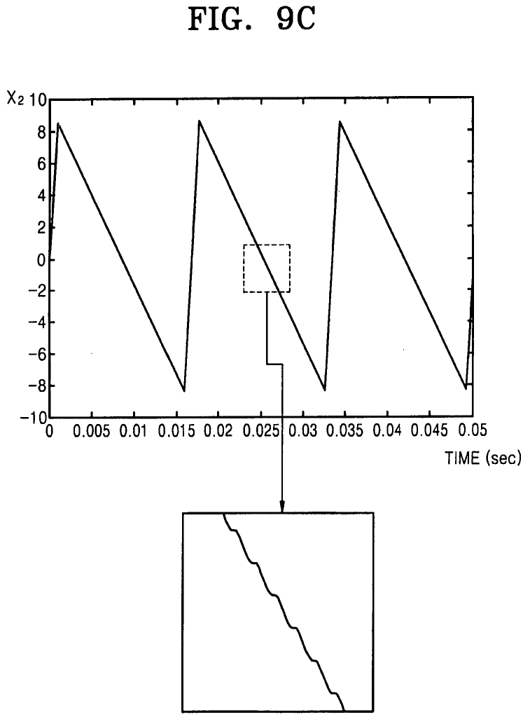

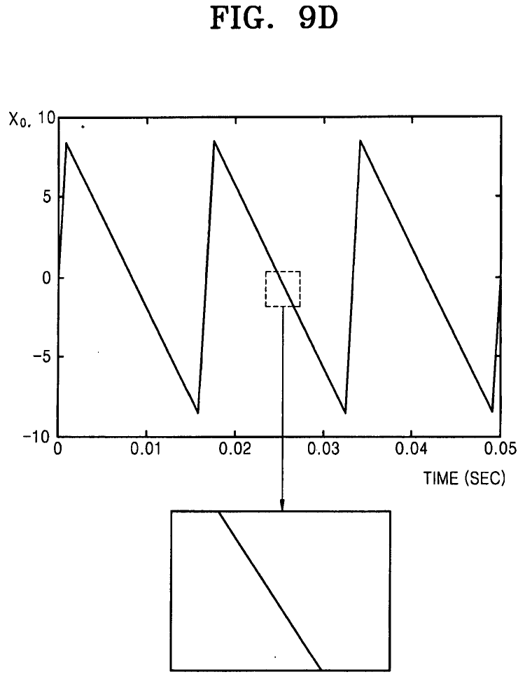

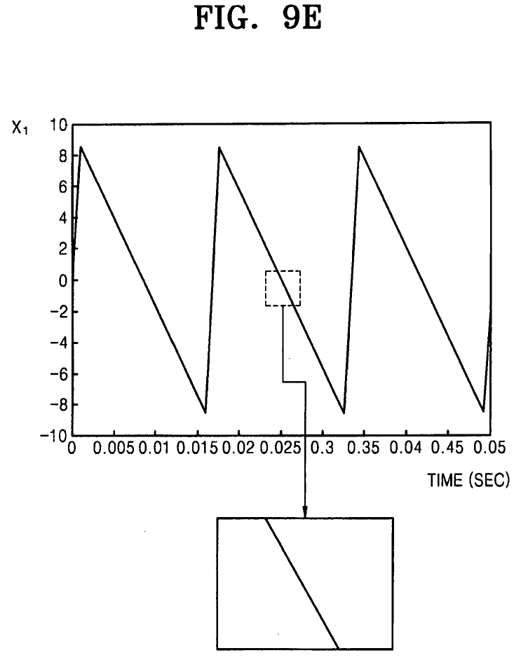

FIGS. 9A and 9B are profile graphs of exciting forces F₀ and F_{pzt} that are respectively exerted on the masses m₀ and m₂. Referring to FIGS. 9A and 9B, the exciting force F₀ can be given in the form of sawtooth waves having a low frequency of 60 Hz, and the exciting force F_{pzt} can be given in the form of sawtooth waves having a high frequency of 50 kHz.

FIG. 9C is a graph illustrating an analysis result for the translational displacement X₂. Referring to FIG. 9C, the mass m₂ vibrates generally according to the low-frequency vibration of the exciting force F₀ (refer to FIG. 9A). As shown in the lower enlarged window in FIG. 9C, the translational displacement curve repeatedly declines and stops in a given falling ramp since the high-frequency vibration of the exciting force F_{pzt} is added to the vibration of the mass m₂. In the MEMS scanner of FIG. 2, which is equivalent to the system shown in FIG. 8, discontinuously declining vertical scanning can be realized by combining a low-frequency vibration and a high-frequency vibration.

FIGS. 9D and 9E are graphs illustrating analysis results for translational displacements X₀ and X₁ of the equivalent system depicted in FIG. 8. Referring to FIGS. 9D and 9E, the transitional displacements X₀ and X₁ of the masses m₀ and m₁ vary according to the low-frequency vibration of the exciting force F₀. As shown in the lower enlarged windows in FIGS. 9D and 9E, the high-frequency vibration of the exciting force F_{pzt} does not affect the transitional displacements X₀ and X₁. In the MEMS scanner of FIG. 2, it is apparent from these analysis results that the high-frequency vibration of the vibration member 115 is not transmitted to the outer frame 100 or the first frame 110.

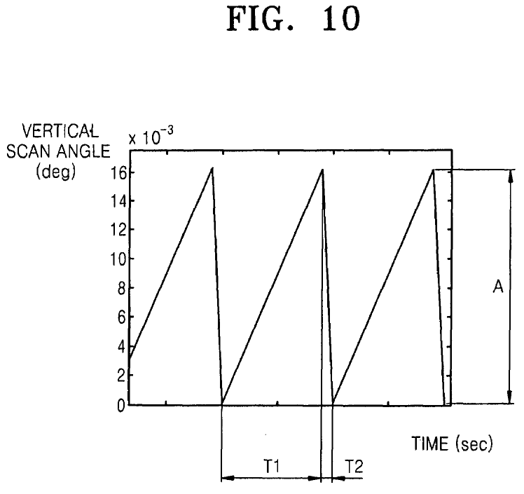

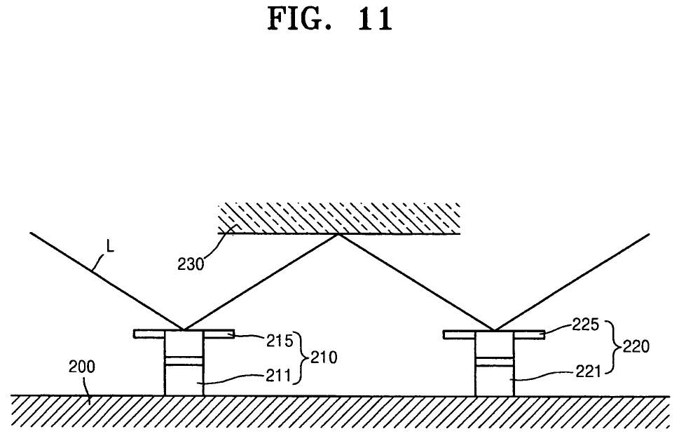

FIG. 10 is a graph illustrating a high-frequency vertical scan function according to an exemplary embodiment of the present invention. Referring to FIG. 10, the high-frequency vertical scan function is given in the form of sawtooth waves having a predetermined high frequency. The horizontal axis represents time, and the vertical axis represents the scan angle in a vertical direction. The sawtooth function exhibits periodical patterns having a relatively slow rising ramp and a steeply falling ramp. The amplitude (A) of the sawtooth waves can be calculated by equation 2 below.

$$A = \frac{{ar}_{h} {f}_{v}}{{r}_{v} {f}_{h}} \qquad [ Equation 2 ]$$

where fₕ and fᵥ denote horizontal and vertical scan frequencies, respectively, and rₕ and rᵥ denote duty ratios. The subscripts h and v are used to represent a horizontal scan function and a high-frequency vertical scan function, respectively. In a horizontal scanning operation using a horizontal scan function (a sinusoidal vibration function), the duty ratio rₕ can be defined as a ratio of a width for sweeping an effective screen region to the peak-to-peak amplitude of the sinusoidal function. Furthermore, in a vertical scanning operation using a high-frequency vertical scan function (sawtooth vibration function), the duty ratio rᵥ can be defined as a ratio of a rising period (T1) where scan line correction is actually carried out to a total period (T1+T2). Furthermore, in Equation 2, “a” denotes the amplitude of a low-frequency vertical scan function and is generally used as ±a.

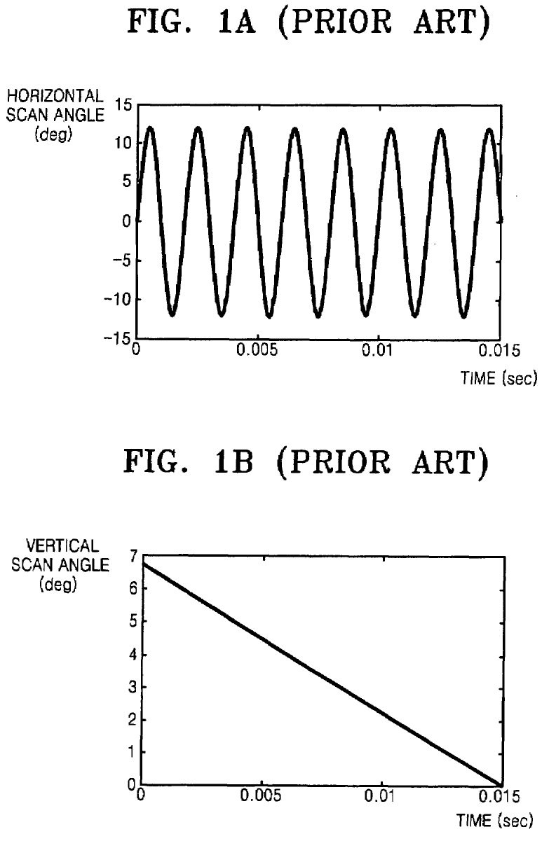

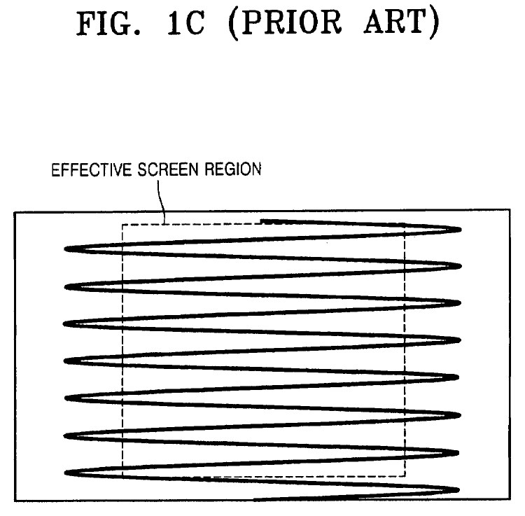

Hereinafter, a MEMS scanner will now be described according to another exemplary embodiment of the present invention. FIG. 11 is a vertical cross-sectional view of a MEMS scanner according to another exemplary embodiment of the present invention. Referring to FIG. 1, the MEMS scanner includes a light source (not shown), a two-dimensional scanner 210 scanning a screen with a light beam (L) emitted from the light source, a compensation scanner 220 adding a high-frequency component to a scan pattern of the two-dimension scanner 210, and a reflection mirror 230 optically connecting the two-dimensional scanner 210 and the compensation scanner 220. The two-dimensional scanner 210 and the compensation scanner 220 can be connected in parallel to each other on the same circuit board 200 and receive a driving signal from the circuit board 200. The light beam (L) emitted from the light source is modulated according to the image data to be displayed. For this, a light modulating unit (not shown) can be provided between the light source and the scanners 210 and 220.

The two-dimensional scanner 210 includes a MEMS mirror 215 and a driving unit 211 driving the MEMS mirror 215 in vibration mode about different axes. The MEMS mirror 215 is used to scan a screen in a horizontal direction and a vertical direction using the light beam (L) emitted from the light source and incident on the MEMS mirror 215. The MEMS mirror 215 may produce horizontal scan lines on a screen while resonating in the form of sinusoidal waves having a frequency of 25 kHz as shown in FIG. 5. Furthermore, the MEMS mirror 215 may be vibrated in a vertical direction at a non-resonant frequency of, for example, 60 Hz as shown in FIG. 6A, so as to move a scan line in a vertical direction. The MEMS mirror 215 and a plate (not shown) supporting the MEMS mirror 215 can be integrally formed on a silicon substrate by patterning the silicon substrate through an etching process. The size and other material properties of the MEMS mirror 215 may be properly selected so that the MEMS mirror 215 can have a resonant frequency of 25 kHz.

The driving unit 211 excites the MEMS mirror 215 in order to rotationally vibrate the MEMS mirror 215 on different axles. For example, the driving unit 211 can excite the MEMS mirror 215 by an electrostatic method or by an electromagnetic method. As long as the driving unit 211 can generate a desired mechanical vibration from a pulse input, the driving unit 211 can employ various driving methods.

Light reflected by the two-dimensional scanner 210 is reflected again by the upper reflection mirror 230 toward the lower compensation scanner 220. The compensation scanner 220 includes a compensation mirror 225 and a driving unit 221 driving the compensation mirror 225 in a rotational vibration mode about an axle. The compensation scanner 220 is separately formed from the two-dimensional scanner 210, so that the compensation scanner 220 vibrates independently of the two-dimensional scanner 210. The compensation scanner 220 adds a high-frequency vertical scan component to the low-frequency vertical scan of the two-dimensional scanner 210. For this, the compensation scanner 220 can be vibrated in the form of sawtooth waves at a non-resonant frequency of 50 kHz as shown in FIG. 6C. Therefore, the low-frequency component of the two-dimensional scanner 210 and the high-frequency component of the compensation scanner 220 can be combined to form a vertical scan pattern in the form of a step function as shown in FIG. 6D. By this combined vertical scan pattern, vertical scanning is not performed while horizontal scanning is performed, so that horizontal scan lines can be produced substantially in a horizontal direction without distortion.

In the current exemplary embodiment, the two-dimension scanner 210 and the compensation scanner 220 are separately provided, so that the two-dimension scanner 210 and the compensation scanner 220 can be independently vibrated. Therefore, the low-frequency vertical scan of the two-dimensional scanner 210 and the high-frequency vertical scan of the compensation scanner 220 can be properly combined without undesired interference therebetween. Accordingly, a desired vertical scan waveform can be precisely obtained. Meanwhile, the two-dimensional scanner 210 and the compensation scanner 220 can be packaged into a single chip so as to provide a single-chip MEMS scanner.

Furthermore, the two-dimensional scanner 210 and the compensation scanner 220 can be arranged regardless of their order. That is, although the two-dimensional scanner 210 is disposed on an optical path prior to the compensation scanner 220 in the exemplary embodiment shown in FIG. 11, the compensation scanner 220 can be disposed adjacent to the light source and then the two-dimensional scanner 210 can be disposed next to the compensation scanner 220.

According to the MEMS scanner of the exemplary embodiments of the present invention, the basic low-frequency scan motion for moving a scan line in a vertical direction is combined with the high-frequency vertical scan motion in order to perform vertical scanning in a multi-step manner, so that the declined horizontal scan line can be corrected. Therefore, horizontal scan lines can be produced substantially in a horizontal direction since vertical scanning is not performed during horizontal scanning. As a result, the horizontal scan lines can be uniformly produced over a screen, and thus the distance between pixels can be evenly maintained, preventing image distortion. Furthermore, the number of horizontal scan lines can be increased for the same screen, so that the vertical resolution of the screen can be increased. Particularly, according to an exemplary embodiment of the present invention, two different vertical scan motion components can be applied to a single mirror instead of adding an additional compensation mirror. Therefore, a small-sized, lightweight, and compact MEMS scanner can be provided.

According to another exemplary embodiment of the present invention, the low-frequency vertical scan motion and the high-frequency vertical scan motion can be independently controlled without interference therebetween. Therefore, a precise vibration control can be accomplished and thus an ideal scan pattern can be obtained by means of the precise vibration control. Furthermore, when the two-dimensional scanner and the compensation scanner are packaged into a single chip, a single-chip MEMS scanner having a compensation function can be provided.

While the present invention has been particularly shown and described with reference to exemplary embodiments thereof, it will be understood by those of ordinary skill in the art that various changes in form and details may be made therein without departing from the spirit and scope of the exemplary embodiments of the present invention as defined by the following claims.

What is claimed is:

1. A micro-electro mechanical system (MEMS) scanner comprising:
a first frame which rotationally vibrates about an axle according to a low-frequency vertical scan function;
a second frame coaxially disposed with respect to the first frame and being rotatably supported by the first frame;
a vibration member disposed between the first frame and the second frame so as to vibrate the second frame with respect to the first frame according to a high-frequency vertical scan function; and
a MEMS mirror which receives a vertical scan motion of the second frame and rotationally vibrates about another axle according to a high-frequency horizontal scan function so as to two-dimensionally scan a screen with incident light.

2. The MEMS scanner of claim 1, wherein the low-frequency vertical scan function comprises sawtooth waves having different rising and falling intervals that repeat at a low frequency.

3. The MEMS scanner of claim 1, wherein the high-frequency vertical scan function comprises sawtooth waves having different rising and falling intervals that repeat at a high frequency.

4. The MEMS scanner of claim 1, wherein the high-frequency horizontal scan function comprises sinusoidal waves having a high frequency.

5. The MEMS scanner of claim 1, wherein the MEMS mirror is operable to vibrate in a resonant mode according to the high-frequency horizontal scan function.

6. The MEMS scanner of claim 1, wherein the high-frequency vertical scan function has a frequency twice as large as that of the high-frequency horizontal scan function.

7. The MEMS scanner of claim 1, wherein the second frame is operable to vibrate according to a step function having a low-frequency vertical scan component of the first frame and a high-frequency vertical scan ripple component of the vibration member.

8. The MEMS scanner of claim 1, wherein the MEMS scanner is configured such that while the MEMS mirror scans the screen for one frame, a scan beam irradiated from the MEMS mirror onto the screen moves down in a vertical direction in a step-by-step manner.

9. The MEMS scanner of claim 1, wherein the MEMS scanner is operable to stop vertical scanning while performing horizontal scanning, and when the horizontal scanning is completed for one horizontal scan line, the MEMS scanner resumes the vertical scanning in order to move down a scan beam spot in a falling manner.

10. The MEMS scanner of claim 1, further comprising an outer frame coaxially connected to the first frame for rotation with the first frame, wherein the first frame is vibrated by an actuator connected to the outer frame according to the low-frequency vertical scan function.

11. The MEMS scanner of claim 1, wherein the MEMS mirror is operable to rotationally vibrate according to the high-frequency horizontal scan function by receiving a torque from an outer frame disposed around the first frame.

12. The MEMS scanner of claim 1, wherein the vibration member is one of an electrostatic material, an electromagnetic material, and a piezoelectric material.

13. The MEMS scanner of claim 1, further comprising an outer frame, wherein the second frame, the first frame, and the outer frame are sequentially disposed around the MEMS mirror, the MEMS mirror and the second frame are connected to each other by a horizontal scan axle, and the first frame and the outer frame are coaxially supported by a vertical scan axle.

14. A micro-electro mechanical system (MEMS) scanner comprising:
a two-dimensional scanner comprising a reflective surface which is disposed to be rotationally vibrated about different axles, the reflective surface reflects light, from a light source, incident on a screen in a horizontal direction and a vertical direction, the reflective surface being rotationally vibrated about one axle according to a high-frequency horizontal scan function and being rotationally vibrated about the other axle according to a low-frequency vertical scan function;
a compensation scanner disposed in parallel to the two-dimensional scanner and comprising a reflection surface vibrated according to a high-frequency vertical scan function; and
a reflection mirror which optically connects the two-dimensional scanner and the compensation scanner.

15. The MEMS scanner of claim 14, wherein the MEMS scanner is operable to perform vertical scanning in a step-by-step falling pattern by combining a low-frequency vertical scan component of the two-dimensional scanner and a high-frequency vertical scan component of the compensation scanner.

16. The MEMS scanner of claim 14, wherein the low-frequency vertical scan function comprises sawtooth waves having a low frequency, and the high-frequency vertical scan function comprises sawtooth waves having a high frequency.

17. The MEMS scanner of claim 14, wherein the high-frequency horizontal scan function comprises sinusoidal waves having a high frequency.

18. The MEMS scanner of claim 14, wherein the high-frequency vertical scan function has a frequency twice as large as that of the high-frequency horizontal scan function.

19. The MEMS scanner of claim 14, wherein the two-dimensional scanner is disposed prior to the compensation scanner along an optical path.

20. The MEMS scanner of claim 14, wherein the compensation scanner is disposed prior to the two-dimensional scanner along an optical path.

21. The MEMS scanner of claim 14, wherein the two-dimensional scanner and the compensation scanner are placed on the same plane, and the reflection mirror is disposed above the two-dimensional scanner and the compensation scanner.

22. The MEMS scanner of claim 14, wherein the two-dimensional scanner and the compensation scanner are packaged into a single chip.

23. A method of vibrating a micro-electro mechanical system (MEMS) scanner, the method comprising:
rotationally vibrating a first frame about an axle according to a low-frequency vertical scan function;
coaxially supporting a second frame with respect to the first frame, such that the second frame is rotatable with respect to the first frame;
vibrating the second frame with respect to the first frame by a vibration member disposed between the first frame and the second frame according to a high-frequency vertical scan function; and
receiving, by a MEMS mirror, a vertical scan motion of the second frame and rotationally vibrating the MEMS mirror about another axle according to a high-frequency horizontal scan function so as to two-dimensionally scan a screen with incident light.

24. The method of claim 23, wherein the method comprises providing sawtooth waves having different rising and falling intervals that repeat at a low frequency for the low-frequency vertical scan function.

25. The method of claim 23, wherein the method comprises providing sawtooth waves having different rising and falling intervals that repeat at a high frequency for the high-frequency vertical scan function.

26. The method of claim 23, wherein the method comprises providing sinusoidal waves having a high frequency for the high-frequency horizontal scan function.

27. The method of claim 23, comprising vibrating the MEMS mirror in a resonant mode according to the high-frequency horizontal scan function.

28. The method of claim 23, wherein the method comprises providing a frequency twice as large as that of the high-frequency horizontal scan function for the high-frequency vertical scan function.

29. The method of claim 23, comprising vibrating the second frame according to a step function having a low-frequency vertical scan component of the first frame and a high-frequency vertical scan ripple component of the vibration member.

30. The method of claim 23, comprising irradiating a scan beam from the MEMS mirror onto the screen such that the scan beam moves down in a vertical direction in a step-by-step manner while the MEMS mirror scans the screen for one frame.

31. The method of claim 23, comprising stopping vertical scanning while performing horizontal scanning, and when the horizontal scanning is completed for one horizontal scan line, resuming the vertical scanning in order to move down a scan beam spot in a falling manner.

32. The method of claim 23, further comprising providing an outer frame coaxially connected to the first frame for rotation with the first frame, and vibrating the first frame by an actuator connected to the outer frame according to a low-frequency vertical scan function.

33. The method of claim 23, comprising rotationally vibrating the MEMS mirror according to the high-frequency horizontal scan function by receiving a torque from an outer frame additionally disposed around the first frame.

34. The method of claim 23, comprising vibrating the second frame by the vibration member by using one of an electrostatic method, an electromagnetic method, and a piezoelectric method.

35. The method of claim 23, comprising providing an outer frame, and sequentially disposing the second frame, the first frame, and the outer frame around the MEMS mirror, connecting the MEMS mirror and the second frame to each other by a horizontal scan axle, and coaxially supporting the first frame and the outer frame by a vertical scan axle.
